(19) United States
(12) Patent Application Publication
(10) Pub. No.: US 2008/0213970 A1
(43) Pub. Date: Sep. 4, 2008

(54) PROCESS FOR THE FORMATION OF DIELECTRIC ISOLATION STRUCTURES IN SEMICONDUCTOR DEVICES

(75) Inventors: Donata PICCOLO, Milano (IT); Lorena Katia Beghin, Milano (IT); Marcello Mariani, Vimercate (Milano) (IT); Chiara Savardi, Sesto San Giovanni (Milano) (IT)

Correspondence Address: CHRISTOPHER F. REGAN, ESQUIRE, ALLEN, DRY, DOPPELT, MILBRATH & GILCHRIST, P.A., P.O. Box 3791, Orlando, FL, 32802-3791, US

(73) Assignee: STMicroelectronics S.r.l., Agrate Brianza (IT)

(21) Appl. No.: 12/014,883

(22) Filed: Jan. 16, 2008

(30) Foreign Application Priority Data
May 26, 2003 (IT) RM2003A000255

(51) Int. Cl. H01L 21/762

(52) U.S. Cl. 438/425; 257/E21.553

(57) ABSTRACT

A process for forming a dielectric isolation structure on a silicon substrate includes forming at least one trench in the substrate, performing a high-temperature treatment in an oxidizing environment to form a first liner layer of silicon dioxide on the walls and the bottom of the trench, and performing a silicon dioxide deposition treatment to form a second liner layer on the first liner layer. A silicon nitride deposition treatment is also performed to form a third liner layer on the second liner layer. The trench is filled with isolating material.

### FIELD OF THE INVENTION

The present invention relates to a process for the formation of a dielectric insulation structure in a semiconductor device.

### BACKGROUND OF THE INVENTION

For the fabrication of integrated circuits having geometries of less than 0.5 μm it is usual to employ a technique, known as STI (Shallow Trench Isolation) for isolating the various parts of an integrated circuit from each other. This technique is briefly described below with reference to FIGS. 1A to 1F and 2A to 2D, which show a section through a part of a silicon slice in the initial fabrication phases of an integrated circuit.

A substrate of monocrystalline silicon 10 is oxidized at a high temperature to obtain a layer 11 of silicon dioxide. A layer 12 of silicon nitride is then deposited on the oxide layer 11 and a photoresist layer 13 is deposited and treated to form a pattern that masks some of the areas of the underlying nitride layer, while leaving others uncovered. By means of an anisotropic attack, usually a plasma attack, the parts of the nitride layer 12 that have been left uncovered are then removed, together with the underlying oxide layer 11. Even the substrate layer is attacked down to a predetermined depth (typically 250-300 nm) to obtain a plurality of grooves or trenches 14. Thereafter, the remainder of the photoresist layer 13 is removed.

To recuperate the damage induced in the silicon by the plasma attack and to form an interface that will facilitate the adhesion of the filler oxide to be subsequently deposited, the substrate is subjected to a high-temperature oxidation phase. On the walls of the trenches there is thus formed a thin layer (15-25 nm) of silicon dioxide 15 (FIG. 2A). But the oxidation process causes surface stresses in the vicinity of the upper and lower corners of the trenches, and these induce defects in the crystalline structure of the silicon (e.g., dislocations). This effect makes itself more strongly felt as the size of the devices that have to be isolated becomes smaller.

These stresses are reduced by depositing a nitride layer 16 (FIG. 2B) on the oxide lining layer 15. For the sake of simplicity, the layers 15 and 16 have not been shown in FIGS. 1A to 1F, and can be seen only in FIGS. 2A to 2D. Silicon dioxide 17 is then deposited (FIGS. 1B and 2C) by a process of the APCVD (Atmospheric Pressure Chemical Vapor Deposition) type, for example, to fill the trenches. The substrate modified in this manner is then subjected to a heat treatment (typically at about 1000° C. for 10-30 minutes to render the oxide 17 denser and then (FIG. 1C) to a planarization treatment by chemical-mechanical polishing to remove the excess oxide layer 17 by using the underlying nitride layer 12 as a stop layer.

Referring now to FIGS. 1D and 2D, the nitride layer 12 and the oxide layer 11 are removed by appropriate wet attacks. During the attack on the oxide, the filler oxide 17 of the trenches is made substantially level with the front surface of the silicon substrate 10. In this phase, nevertheless, some small grooves 18 are formed in the oxide 17 along the edges of the trenches 14. This is brought about by the fact that the attack solution used to remove the oxide layer 11, usually HF, attacks the filler oxide 17, which is deposited oxide, more rapidly than the oxide of the layer 11, which is thermal oxide. The small grooves 18 are also due to the fact that the attack is isotropic and therefore acts also laterally on the filler oxide 17.

As is shown in FIG. 2D, at the end of the attack on the oxide there remain parts in relief 19 within the grooves 18. These parts in relief 19 are made up of the edges of the nitride layers 16 that are part of the trench lining and are not attacked by the solution with which the oxide is attacked. These parts in relief 19 may cause defects of a morphological and electrical nature because they perform an undesired screening action during the subsequent attacks with the consequent formation of spurious structural elements caused by material residues. If these effects are to be attenuated, the process parameters of the attack operations have to be calibrated with great precision. Nevertheless, for example, in the case of an integrated circuit containing a memory with polysilicon floating gate cells, electrical failures due to short circuits between the memory cells caused by polycrystalline silicon residues are very probable. Consequently, use of the isolation structure described above implies relatively low production yields.

### SUMMARY OF THE INVENTION

An object of the present invention is to propose a process that will make it possible to form dielectric isolation structures that do not provoke or, at least, diminish the defects described above, especially crystallographic defects.

This and other objects, advantages and features in accordance with the present invention are provided by a process for forming a dielectric isolation structure on a silicon substrate. The process may comprise forming a first silicon dioxide isolation layer on the silicon substrate, forming a layer of conductive material on the silicon dioxide isolation layer, forming a second silicon dioxide isolation layer on the layer of conductive material, and forming a silicon nitride cover layer on the second silicon dioxide isolation layer.

At least one trench having sidewalls and a bottom may be formed in the silicon substrate. More particularly, the forming may comprise forming a mask on the silicon nitride cover layer for defining an area to be removed for the at least one trench, and removing a portion of the silicon nitride cover layer, a portion of the second silicon dioxide isolation layer, a portion of the layer of conductive material and a portion of the silicon substrate to a depth below a surface thereof.

The method may further comprise forming a first liner layer of silicon dioxide on the sidewalls and the bottom of the at least one trench, with the first liner layer being formed based upon a high-temperature treatment in an oxidizing environment. A second liner layer of silicon dioxide may be formed on the first liner layer, with the second liner layer being formed based upon a deposition treatment. A third liner layer of silicon nitride may be formed on the second liner layer. The at least one trench may then be filled with isolation material.

Filling the at least one trench may comprise depositing the isolation material on the third liner layer. The method may further comprise planarizing the isolation structure by partially removing the isolation material until an area of the third liner layer delimiting the at least one trench is uncovered, removing the silicon nitride cover layer and the second silicon dioxide isolation layer, and removing a portion of the isolation material that fills the at least one trench so that an upper surface of the isolation material in the at least one trench is lower than an upper surface of the layer of conductive material.

### BRIEF DESCRIPTION OF THE DRAWINGS

The invention will be more readily understood from the detailed description of two embodiments of the process, which are described by way of example and are not to be regarded as limiting in any way. The description makes reference to the attached drawings, of which:

FIGS. 1A to 1F show a section through a portion of an isolation structure in accordance with the prior art;

FIGS. 2A to 2D show a section through a portion of an isolation structure in accordance with the prior art in which there can be seen some details not shown in FIGS. 1A to 1F;

FIGS. 3A to 3D show a section through a portion of an isolation structure formed by the process in accordance with the present invention; and

FIGS. 4A to 4E show a section through a portion of an isolation structure formed by another embodiment of the process in accordance with the present invention.

### DETAILED DESCRIPTION OF THE PREFERRED EMBODIMENTS

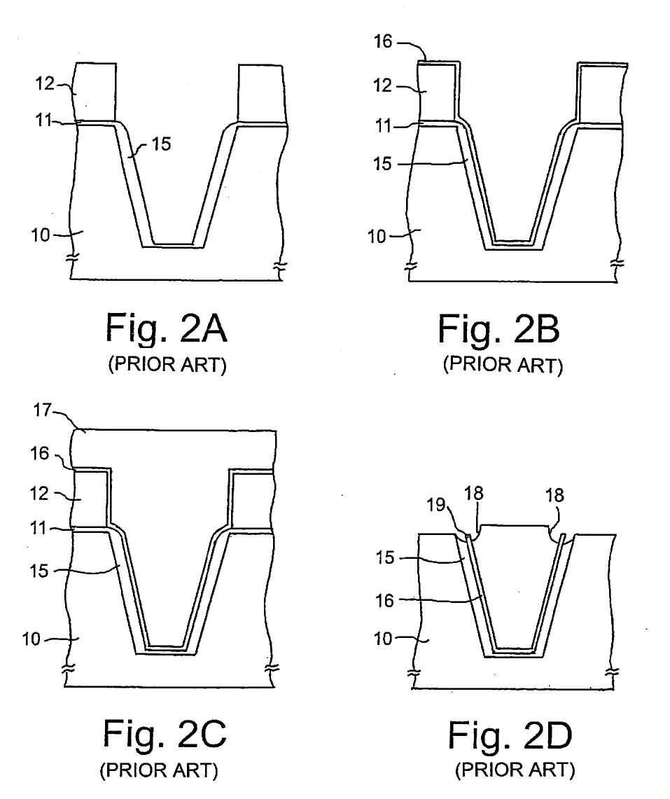

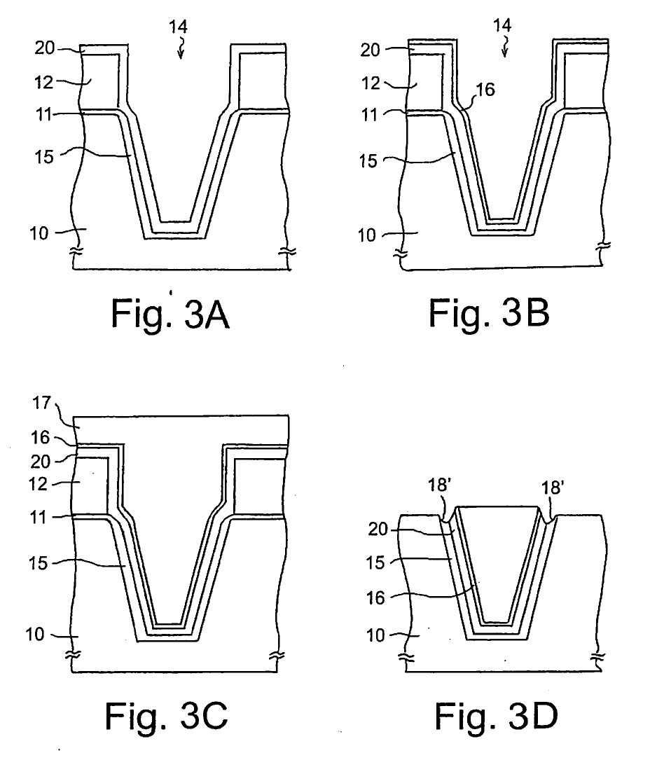

Referring to FIGS. 3A to 3D, wherein the portions equal to those of FIGS. 2A to 2D are indicated by the same reference numbers, the process in accordance with the invention differs from the known process described above by virtue of the fact that, following the formation of the layer 15 lining the trenches 14 by high-temperature oxidation of the silicon, a silicon dioxide deposition treatment is performed, for example, by a process of the APCVD type. On the first thermal oxide layer 15 there is thus formed a second deposited oxide layer 20.

The process then continues, just like the known process, with the deposition of a silicon nitride layer 16, the deposition of silicon dioxide 17 to fill the trenches 14, the planarization and the removal of the surface nitride and oxide layers, respectively, 12 and 11. Even in this case some grooves will be formed, indicated by 18′ in FIG. 3D, along the edges of the trenches. Nevertheless, due to the thickening of the oxide lining, the nitride layer is sufficiently distant from the silicon walls of the trenches to assure that the grooves will extend only between the edge of the trench and the nitride layer 16, so that the edge of the nitride layer does not remain within the groove as in the known process.

The screening action described above in connection with the known process does not take place because the nitride layer 16 does not form parts in relief. At the same time, the nitride layer 16 efficiently performs its screening action with respect to the oxidizing species, which in the course of the fabrication process could arrive at the silicon of the trench walls and thus give rise to crystallographic defects. Naturally, the process parameters, and therefore the thicknesses of the layers, have to be chosen in a manner known to persons skilled in the art to assure that the overall thickness of the oxide lining of the trenches will be sufficient to insure this effect.

By way of general orientation, an isolation structure formed in accordance with the invention may be characterized by the following dimensions. The mean width of the trenches 14 is between 180 nm and 70 nm. The depth of the trenches 14 is between 350 nm and 100 nm. The thickness of the first lining layer 15 is between 30 nm and 5 nm. The thickness of the second lining layer 20 is between 50 nm and 5 nm. The thickness of the nitride layer 16 is between 15 nm and 3 nm.

A particularly advantageous application of the process in accordance with the invention concerns the isolation of a memory formed by cells having gate electrodes self-aligned with the active areas adjacent to the trenches.

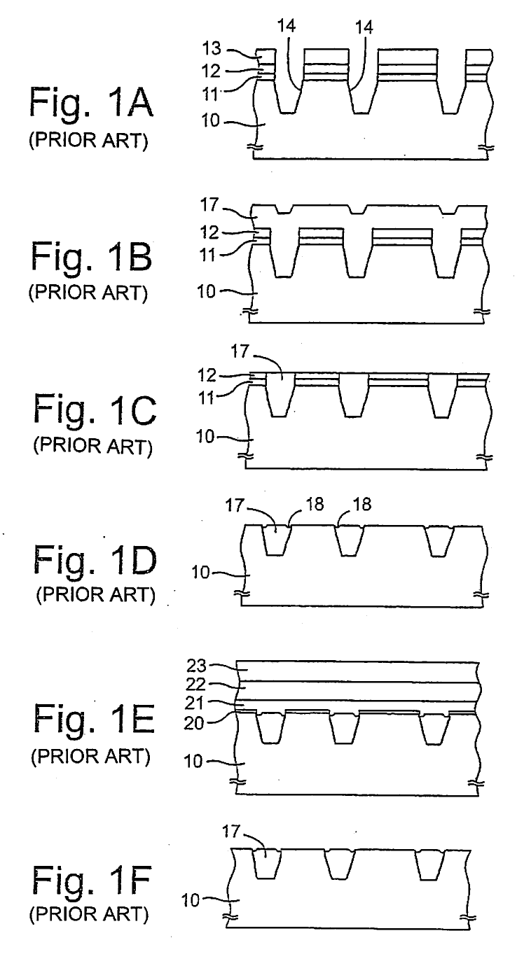

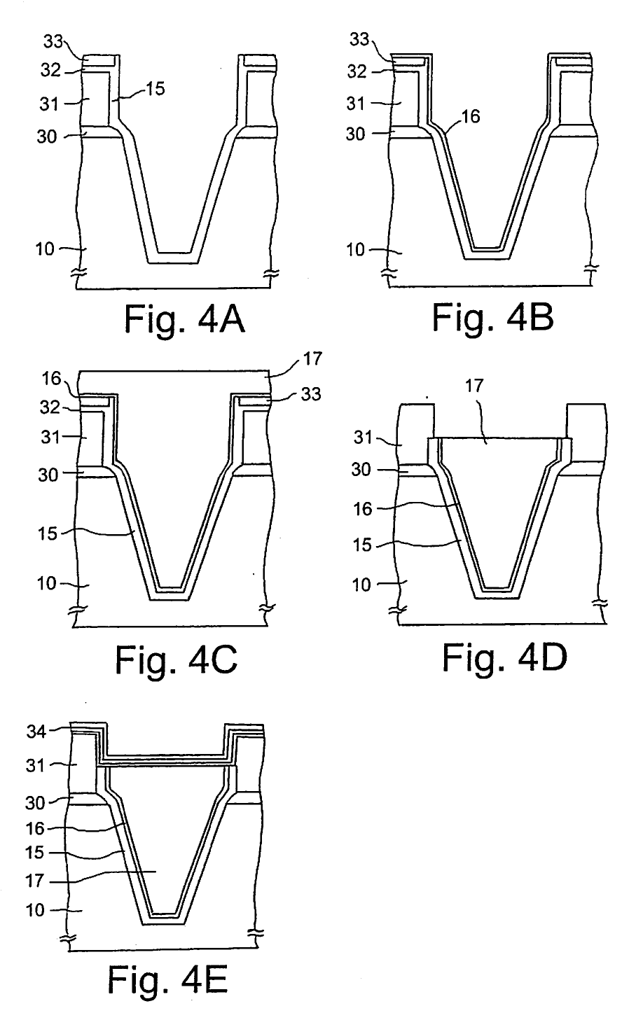

FIGS. 4A to 4E, wherein portions equal to the corresponding portions of FIGS. 3A to 3D are indicated by the same reference numbers, show a portion of a monocrystalline silicon substrate 10 containing a trench 14 of an isolation structure obtained by a process in accordance with the invention. The process envisages high-temperature oxidation of the surface of the substrate 10 to obtain a thin layer (10 nm) 30 of silicon dioxide to form the so-called tunnel dielectric of the memory cells, the deposition of a layer 31 of polycrystalline silicon to form the floating gate electrodes of the cells, the deposition of a thin layer (15 nm) 32 of silicon dioxide and the deposition of a stop layer 33 of silicon nitride. The process continues with operations, similar to those described in connection with FIGS. 1A to 1F and FIGS. 3A to 3D, for the definition of the areas where the trenches are to be formed and for carrying out the removal of the corresponding material.

At the end of the material removal one thus obtains a cavity that forms the trench 14, which extends into the silicon substrate 10, and an aperture across the superposed layers 30 to 33 that combines with the trench and forms its entrance. In this case, once again, the process then envisages the formation of a first lining layer 15 of thermal oxide, a second lining layer 20 of deposited oxide (FIG. 4A) and a silicon nitride layer 16 (FIG. 4B), deposition of silicon dioxide 17 (FIG. 4C) to fill the trenches and, lastly, planarization. The nitride layer 33, which forms the stop layer of the planarization operation, is then removed by a wet attack together with the underlying oxide layer 32 and also a part of the filler oxide (17+16+15).

In this phase the filler oxide is attacked down to a level lower than that of the polycrystalline silicon 31 so that the floating gate electrode has part of its side uncovered, as can be seen in FIG. 4D. Subsequently there is formed a composite layer 34 (FIG. 4E) to isolate the floating gate electrodes from the control gate electrodes (which will be formed later). This is achieved by a means of subsequent deposition of a first oxide layer, an intermediate silicon nitride layer and a second oxide layer, the so-called ONO (Oxide-Nitride-Oxide) dielectric, which makes it possible to seal the side with nitride already present on the side of the floating gate electrodes of the memory cells. This assures optimal electrical isolation of the cells and optimal capacitative coupling between the floating gate electrodes and the silicon substrate.

The process described above makes it possible to form a memory (of the NAND or NOR type, Stand Alone or Embedded) and a circuit portion on the same silicon substrate with the possibility of integrating the standard isolation with a nitride lining isolation either only in the memory cells, or only in the circuit part, or in both memory cells and circuit part. This implies considerable advantages in terms of degrees of freedom of the overall process and in terms of yield. The advantage for the cell is given by the improvement of the capacitative coupling and the sealing of the gate, together with the elimination or drastic reduction of the dislocations. The advantage for the circuit part is represented by the elimination or drastic reduction of the dislocations.

According to two variations of the process described in relation to FIGS. 4A to 4E, the lining of the trenches to isolate the memory cells from each other may also be carried out, rather than by forming two oxide layers (one thermal, the other deposited) and a nitride layer, by forming a single oxide layer by deposition and then subjecting this layer to nitriding or by forming an oxide layer by deposition and a nitride layer. These variations do not consent the simultaneous formation of the isolation structure of the memory and the corresponding structure of the circuit part when the latter has to have an isolation of the type described by FIGS. 3A to 3D. The two isolation structures will in this case be formed partly by distinct operations, utilizing an appropriate masking, and partly by common operations, i.e., the operations of planarization and the operations of wet attack.

1-7. (canceled)

8. A process for forming a dielectric isolation structure on a silicon substrate, the process comprising:
forming a first silicon dioxide isolation layer on the silicon substrate;
forming a layer of conductive material on the silicon dioxide isolation layer;
forming a second silicon dioxide isolation layer on the layer of conductive material;
forming a silicon nitride cover layer on the second silicon dioxide isolation layer;
forming in the silicon substrate at least one trench having sidewalls and a bottom, the forming comprising
forming a mask on the silicon nitride cover layer for defining an area to be removed for the at least one trench, and
removing a portion of the silicon nitride cover layer, a portion of the second silicon dioxide isolation layer, a portion of the layer of conductive material and a portion of the silicon substrate to a depth below a surface thereof;
forming a first liner layer of silicon dioxide on the sidewalls and the bottom of the at least one trench, the first liner layer being formed based upon a high-temperature treatment in an oxidizing environment;
forming a second liner layer of silicon dioxide on the first liner layer, the second liner layer being formed based upon a deposition treatment;
forming a third liner layer of silicon nitride on the second liner layer; and
filling the at least one trench with isolation material.

9. A process in accordance with claim 8, wherein filling the at least one trench comprises depositing the isolation material on the third liner layer; and further comprising planarizing the isolation structure by:
partially removing the isolation material until an area of the third liner layer delimiting the at least one trench is uncovered;
removing the silicon nitride cover layer and the second silicon dioxide isolation layer; and
removing a portion of the isolation material that fills the at least one trench so that an upper surface of the isolation material in the at least one trench is lower than an upper surface of the layer of conductive material.

10. A process in accordance with claim 9, further comprising forming a composite layer comprising silicon nitride on the exposed layer of conductive material, on the exposed first, second and third liner layers, and on the exposed upper surface of the insulation material.

11. A process for forming an integrated circuit on a silicon substrate having a first area with a first dielectric isolation structure and a second area with a second dielectric isolation structure, the process comprising:
forming the first dielectric isolation structure comprising
forming in the silicon substrate at least one trench having sidewalls and a bottom,
forming a first liner layer of silicon dioxide on the sidewalls and the bottom of the at least one trench based upon a high-temperature treatment in an oxidizing environment,
performing a nitride treatment of the first liner layer, and
filling the at least one trench with isolation material; and
forming the second dielectric isolation structure comprising
forming in the silicon substrate at least one trench having sidewalls and a bottom,
forming a first liner layer of silicon dioxide on the sidewalls and the bottom of the at least one trench, the first liner layer being formed based upon a high-temperature treatment in an oxidizing environment,
forming a second liner layer of silicon dioxide on the first liner layer, the second liner layer being formed based upon a deposition treatment,
forming a third liner layer of silicon nitride on the second liner layer, and
filling the at least one trench with isolation material.

12. A process in accordance with claim 11, for the second dielectric isolation structure, wherein forming the third liner layer is based upon a deposition treatment.

13. A process in accordance with claim 11, for the second dielectric isolation structure, wherein prior to forming the at least one trench, further comprising:
forming a silicon dioxide isolation layer on the silicon substrate; and
forming a silicon nitride cover layer on the silicon dioxide isolation layer;
wherein forming the at least one trench comprises forming a mask on the silicon nitride cover layer for defining an area to be removed for the at least one trench, and removing a portion of the silicon nitride cover layer, a portion of the silicon dioxide isolation layer and a portion of the silicon substrate to a depth below a surface of the silicon substrate.

14. A process in accordance with claim 13, for the second dielectric isolation structure, wherein filling the at least one trench comprises depositing the isolation material on the third liner layer; and further comprising planarizing the dielectric isolation structure by:
partially removing a portion of the isolation material until the third liner layer delimiting the at least one trench is uncovered;
removing the silicon dioxide isolation layer and the silicon nitride cover layer; and
removing a portion of the silicon substrate to a depth below a surface thereof.

15. A process in accordance with claim 11, for the second dielectric isolation structure, wherein prior to forming the at least one trench, further comprising:
forming a first silicon dioxide isolation layer on the silicon substrate;
forming a layer of conductive material on the silicon dioxide isolation layer;
forming a second silicon dioxide isolation layer on the layer of conductive material; and
forming a silicon nitride cover layer on the second silicon dioxide isolation layer;
wherein forming the at least one trench comprises forming a mask on the silicon nitride cover layer for defining an area to be removed for the at least one trench, and removing a portion of the silicon nitride cover layer, a portion of the second silicon dioxide isolation layer, a portion of the layer of conductive material and a portion of the silicon substrate to a depth below a surface thereof.

16. A process in accordance with claim 15, for the second dielectric isolation structure, wherein filling the at least one trench comprises depositing the isolation material on the third liner layer; and further comprising planarizing the isolation structure by:
partially removing the isolation material until an area of the third liner layer delimiting the at least one trench is uncovered;
removing the silicon nitride cover layer and the second silicon dioxide isolation layer; and
removing a portion of the isolation material that fills the at least one trench so that an upper surface of the isolation material in the at least one trench is lower than an upper surface of the layer of conductive material.

17. A process in accordance with claim 16, for the second dielectric isolation structure, further comprising forming a composite layer comprising silicon nitride on the exposed layer of conductive material, on the exposed first, second and third liner layers, and on the exposed upper surface of the insulation material.

18. A process for forming an integrated circuit on a silicon substrate having a first area with a first dielectric isolation structure and a second area with a second dielectric isolation structure, the process comprising:
forming the first dielectric isolation structure comprising
forming at least one trench in the silicon substrate,
forming a first liner layer silicon dioxide on the sidewalls and the bottom of the at least one trench based upon a high-temperature treatment in an oxidizing environment,
forming a second liner layer of silicon nitride on the first liner layer based upon a deposition treatment, and
filling the at least one trench with isolation material; and
forming the second dielectric isolation structure comprising
forming in the silicon substrate at least one trench having sidewalls and a bottom,
forming a first liner layer of silicon dioxide on the sidewalls and the bottom of the at least one trench, the first liner layer being formed based upon a high-temperature treatment in an oxidizing environment,
forming a second liner layer of silicon dioxide on the first liner layer, the second liner layer being formed based upon a deposition treatment,
forming a third liner layer of silicon nitride on the second liner layer, and
filling the at least one trench with isolation material.

19. A process in accordance with claim 18, for the second dielectric isolation structure, wherein forming the third liner layer is based upon a deposition treatment.

20. A process in accordance with claim 18, for the second dielectric isolation structure, wherein prior to forming the at least one trench, further comprising:
forming a silicon dioxide isolation layer on the silicon substrate; and
forming a silicon nitride cover layer on the silicon dioxide isolation layer;
wherein forming the at least one trench comprises forming a mask on the silicon nitride cover layer for defining an area to be removed for the at least one trench, and removing a portion of the silicon nitride cover layer, a portion of the silicon dioxide isolation layer and a portion of the silicon substrate to a depth below a surface of the silicon substrate.

21. A process in accordance with claim 20, for the second dielectric isolation structure, wherein filling the at least one trench comprises depositing the isolation material on the third liner layer; and further comprising planarizing the dielectric isolation structure by:
partially removing a portion of the isolation material until the third liner layer delimiting the at least one trench is uncovered;
removing the silicon dioxide isolation layer and the silicon nitride cover layer; and
removing a portion of the silicon substrate to a depth below a surface thereof.

22. A process in accordance with claim 18, for the second dielectric isolation structure, wherein prior to forming the at least one trench, further comprising:
forming a first silicon dioxide isolation layer on the silicon substrate;
forming a layer of conductive material on the silicon dioxide isolation layer;
forming a second silicon dioxide isolation layer on the layer of conductive material; and
forming a silicon nitride cover layer on the second silicon dioxide isolation layer;
wherein forming the at least one trench comprises forming a mask on the silicon nitride cover layer for defining an area to be removed for the at least one trench, and removing a portion of the silicon nitride cover layer, a portion of the second silicon dioxide isolation layer, a portion of the layer of conductive material and a portion of the silicon substrate to a depth below a surface thereof.

23. A process in accordance with claim 22, for the second dielectric isolation structure, wherein filling the at least one trench comprises depositing the isolation material on the third liner layer; and further comprising planarizing the isolation structure by:
partially removing the isolation material until an area of the third liner layer delimiting the at least one trench is uncovered;
removing the silicon nitride cover layer and the second silicon dioxide isolation layer; and
removing a portion of the isolation material that fills the at least one trench so that an upper surface of the isolation material in the at least one trench is lower than an upper surface of the layer of conductive material.

24. A process in accordance with claim 23, for the second dielectric isolation structure, further comprising forming a composite layer comprising silicon nitride on the exposed layer of conductive material, on the exposed first, second and third liner layers, and on the exposed upper surface of the insulation material.
